(19) United States
(12) Patent Application Publication
(10) Pub. No.: US 2006/0085706 A1
(43) Pub. Date: Apr. 20, 2006

(54) High speed on chip testing

(76) Inventor: Kevin J. Gearhardt, Fort Collins, CO (US)

Correspondence Address: LSI LOGIC CORPORATION, 1621 BARBER LANE, MS: D-106, MILPITAS, CA, 95035, US

(21) Appl. No.: 10/957,788

(22) Filed: Oct. 4, 2004

(51) Int. Cl. G01R 31/28

(52) U.S. Cl. 714/724

(57) ABSTRACT

A selectively enabled clock doubler. An XOR gate receives a first signal on a first input and a second signal on a second input, and provides a third signal on an output. The first signal is a clock signal having a first frequency. A delay circuit receives the clock signal and delays the clock signal by about ninety degrees. A control circuit selectively activates the delay circuit to provide the delayed clock signal as the second signal, and selectively deactivates the delay circuit to provide a low signal as the second signal. A buffer receives the third signal and provides the third signal as a buffered third signal that has a third frequency. The third frequency is about twice the first frequency when the second signal is the delayed clock signal, and the third frequency is about the first frequency when the second signal is the low signal.

### FIELD

This invention relates to the field of integrated circuit fabrication. More particularly, this invention relates to electrical testing of integrated circuits.

### BACKGROUND

As the term is used herein, “integrated circuit” includes devices such as those formed on monolithic semiconducting substrates, such as those formed of group IV materials like silicon or germanium, or group III-V compounds like gallium arsenide, or mixtures of such materials. The term includes all types of devices formed, such as memory and logic, and all designs of such devices, such as MOS and bipolar. The term also comprehends applications such as flat panel displays, solar cells, and charge coupled devices.

To meet the quality level expectations placed on modem integrated circuits, it is becoming more critical for the memories which are instantiated within a device-under-test to be tested at targeted application frequencies, or as close as the automated test equipment can facilitate. The challenge being faced is that the majority of testers which are in use, particularly the lower cost tester platforms, cannot provide the needed clock speeds to facilitate such testing of the memories. With 130 nanometer technology ramping up, and 90 nanometer technology on the horizon, the 200 megahertz test rate available on these lower cost test platforms is not adequate to properly run the needed tests. A higher speed solution is needed on these existing tester platforms, without having to spend significant capital resources to upgrade to newer tester platforms.

The only real existing solution to the aforementioned problem is to purchase newer tester platforms that can support test frequencies well beyond the current 200 megahertz limitation. The capital expenditures required for such a solution are not feasible.

What is needed, therefore, is a system that overcomes problems such as those described above, at least in part.

### SUMMARY

The above and other needs are met by a selectively enabled clock doubler. An XOR gate receives a first signal on a first input and a second signal on a second input, and provides a third signal on an output. The first signal is a clock signal having a first frequency. A delay circuit receives the clock signal and delays the clock signal by about ninety degrees. A control circuit selectively activates the delay circuit to provide the delayed clock signal as the second signal, and selectively deactivates the delay circuit to provide a low signal as the second signal. A buffer receives the third signal and provides the third signal as a buffered third signal that has a third frequency. The third frequency is about twice the first frequency when the second signal is the delayed clock signal, and the third frequency is about the first frequency when the second signal is the low signal.

In this manner, the clock doubler can provide a signal at a frequency that is higher than the maximum frequency that can be produced by the tester. Thus, the clock doubler enables an older, slower tester to effectively test newer, higher frequency circuits, such as high speed memory.

In various preferred embodiments of the invention, the clock doubler is implemented as part of a built in self test circuit for high speed memory. The clock signal is preferably generated by a tester. Preferably, the first frequency is about two hundred megahertz and the third frequency is about four hundred megahertz. Also described is an integrated circuit that includes the clock doubler.

According to another aspect of the invention there is described an integrated circuit having a selectively enabled clock doubler. An XOR gate receives a first signal on a first input and a second signal on a second input, and provides a third signal on an output. The first signal is a clock signal having a first frequency, where the clock signal is received from a tester on an input of the integrated circuit. A delay circuit receives the clock signal and delays the clock signal by about ninety degrees. A control circuit selectively activates the delay circuit to provide the delayed clock signal as the second signal, and selectively deactivates the delay circuit to provide a low signal as the second signal. The control signal is selectively activated and deactivated by a signal received by the integrated circuit from the tester. A buffer receives the third signal and provides the third signal as a buffered third signal. The third signal has a third frequency, where the third frequency is about twice the first frequency when the second signal is the delayed clock signal and the third frequency is about the first frequency when the second signal is the low signal. The third frequency is a higher frequency than the tester can produce.

In preferred embodiments of this aspect of the invention, the clock doubler is implemented as part of a built in self test circuit for high speed memory, where the first frequency is about two hundred megahertz and the third frequency is about four hundred megahertz.

According to yet another aspect of the invention there is described a method for testing a high speed circuit on an integrated circuit at a high frequency that is higher than a tester frequency that is produced by a tester that is performing the testing. A tester clock signal having the tester frequency is produced with the tester, and is provided to the integrated circuit through a first input on the integrated circuit. The tester clock signal is routed to a first input on an XOR gate, and to a delay circuit that is operable to produce a delayed clock signal at the tester frequency. A control signal is produced with the tester, and is provided to the integrated circuit through a second input on the integrated circuit, and routed to the delay circuit.

The control signal selectively engages and disengages the delay circuit based on tester settings, where the delay circuit produces the delayed clock signal as a delay circuit output when the delay circuit is engaged, and produces a low signal as the delay circuit output when the delay circuit is disengaged. The delay circuit output is routed to a second input on the XOR gate, thereby producing a test signal with the high frequency at an output of the XOR gate when the delay circuit is engaged and producing the test signal with the tester frequency when the delay circuit is disengaged. The test signal is selectively routed to the high speed circuit.

In various embodiments of this aspect of the invention, the method is implemented as part of a built in self test procedure for a high speed memory that operates at the high frequency. In some embodiments the high frequency is greater than the test frequency that the tester can produce. In many embodiments the tester frequency is about two hundred megahertz and the high frequency is about four hundred megahertz. Most preferably the high frequency is about twice the tester frequency.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a functional block diagram of the clock doubler circuit according to a preferred embodiment of the invention.

FIG. 2 depicts the inputs and output on the XOR gate of the clock doubler, according to a preferred embodiment of the invention.

### DETAILED DESCRIPTION

The various embodiments of the present invention provide a solution to the aforementioned testing problem, by adding circuitry to the design of the integrated circuit prior to releasing it for processing. The added circuitry preferably functions as a selectable clock speed doubler that is selectively switched on and off as desired during the course of a test cycle, such that the lower speed clocks are preferably used during conditioning and setup for the built in self test operation, while the doubled clock frequency is preferably enabled during the actual execution of the built in self test algorithm.

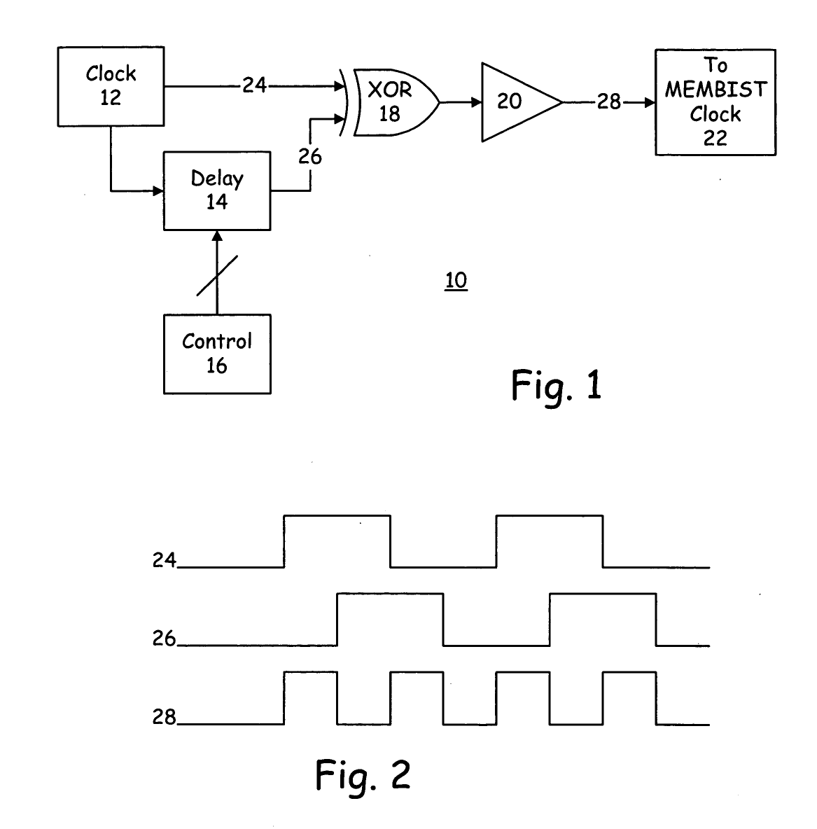

In a preferred embodiment, as depicted in FIG. 1, the circuitry 10 consists of an XOR gate 18 that is driven by two inputs 24 and 26, the first of which 24 is the original clock signal 12 coming from the automated test equipment, and the second of which 26 is a delayed version of that same clock signal 12 that goes through a delay circuit 14. The output 28 of the XOR gate 18 is sent through a buffer 20 and supplied to the clock circuit 22, which drives the test logic on the device.

The Delay/MUX circuit 14 as depicted in FIG. 1 is preferably controlled by programming the necessary on-chip test logic 16 such that an appropriately delayed clock derived from the tester-supplied clock 12 is then combined via the XOR gate 18 to generate a high-speed clock stream 28 which is twice the tester's clock speed 12 that is used for the high speed memory built in self test (MEMBIST) clocks, as depicted in FIG. 2. Based on the processing of a given device, which is known from other on-chip process monitoring circuitry, the delay 14 is preferably set to provide a second clock 26 which is about ninety degrees out of phase from the original signal 24. The Delay/MUX circuit 14 can also be disabled during the course of a test execution, such that the resultant output of the XOR gate 18 is simply a buffered version of the originating clock signal 24 provided by the automated test equipment.

The 200 megahertz clock signal 24 shown to be coming from the tester preferably has about a fifty percent duty cycle, as the rising and falling edges of the high pulse preferably determine the period of the resultant clock 28 coming from the XOR gate 18. At 200 megahertz, for example, the tester's 12 clock pulse width is about 2.5 nanoseconds with about a five nanosecond period. The delayed clock 26 from the Delay/MUX circuit 14 is preferably delayed by about half the pulse width, or about 1.25 nanoseconds for a 200 megahertz reference clock 24, to provide a fifty percent duty cycle on the resulting 400 megahertz clock 28 sent to the MEMBIST test circuitry 22. The Delay/MUX circuit can be disabled by the control circuitry 16 that drives it, such that the output of the delay 14 is held low, and the tester generated clock signal 24 is simply passed through the XOR gate 18. The ability to disable the delay circuit 14 allows the user to control the MEMBIST test clock, 22, which would not be afforded by using, for example, an on-chip phase lock loop as a clock doubler.

An important feature of the present invention is to provide a 2× clock multiplier 10, such as for MEMBIST testing, which multiplier 10 is under the control of the test system. The more common approach of using an on-chip phase lock loop to provide the clock multiplication cannot easily be controlled with respect to shutting down the on-chip multiplied clock, which is a critical component of post-manufacturing device analysis and failure analysis.

Since the logic 10 to generate the high-speed clock is implemented on the actual integrated circuit to be tested, the maximum frequency which can be generated of twice the clock speed 12 provided by the automated test equipment will not exceed the performance of the process technology associated with the design, given today's process technologies. This provides twice the capability for high-speed MEMBIST testing relative to a 200 megahertz capable automated test equipment.

It is appreciated that, although an example is provided above with respect to a 200 megahertz clock from the test equipment, the present invention is also applicable to any test application which requires a high-speed controllable clock that exceeds the available tester's capabilities, even at tester speeds that are greater than 200 megahertz.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A selectively enabled clock doubler, comprising:
an XOR gate for receiving a first signal on a first input and a second signal on a second input, and further for providing a third signal on an output,
the first signal comprising a clock signal having a first frequency,
a delay circuit for receiving the clock signal and delaying the clock signal by about ninety degrees,
a control circuit for selectively activating the delay circuit to provide the delayed clock signal as the second signal, and selectively deactivating the delay circuit to provide a low signal as the second signal, and
a buffer for receiving the third signal and providing the third signal as a buffered third signal,
where the third signal has a third frequency, where the third frequency is about twice the first frequency when the second signal is the delayed clock signal and the third frequency is about the first frequency when the second signal is the low signal.

2. The clock doubler of claim 1, wherein the clock doubler is implemented as part of a built in self test circuit for high speed memory.

3. The clock doubler of claim 1, wherein the clock signal is generated by a tester.

4. The clock doubler of claim 1, wherein the first frequency is about two hundred megahertz and the third frequency is about four hundred megahertz.

5. In an integrated circuit, the improvement comprising the clock doubler of claim 1.

6. An integrated circuit having a selectively enabled clock doubler, comprising:
an XOR gate for receiving a first signal on a first input and a second signal on a second input, and further for providing a third signal on an output,
the first signal is a clock signal having a first frequency, where the clock signal is received from a tester on an input of the integrated circuit,
a delay circuit for receiving the clock signal and delaying the clock signal by about ninety degrees,
a control circuit for selectively activating the delay circuit to provide the delayed clock signal as the second signal, and selectively deactivating the delay circuit to provide a low signal as the second signal, where the control signal is selectively activated and deactivated by a signal received by the integrated circuit from the tester, and
a buffer for receiving the third signal and providing the third signal as a buffered third signal,
where the third signal has a third frequency, where the third frequency is about twice the first frequency when the second signal is the delayed clock signal and the third frequency is about the first frequency when the second signal is the low signal, and the third frequency is a higher frequency than the tester can produce.

7. The clock doubler of claim 6, wherein the clock doubler is implemented as part of a built in self test circuit for high speed memory.

8. The clock doubler of claim 6, wherein the first frequency is about two hundred megahertz and the third frequency is about four hundred megahertz.

9. A method for testing a high speed circuit on an integrated circuit at a high frequency that is higher than a tester frequency that is produced by a tester that is performing the testing, the method comprising the steps of:
producing a tester clock signal having the tester frequency with the tester,
providing the tester clock signal to the integrated circuit through a first input on the integrated circuit,
routing the tester clock signal to a first input on an XOR gate,
routing the tester clock signal to a delay circuit that is operable to produce a delayed clock signal at the tester frequency,
producing a control signal with the tester,
providing the control signal to the integrated circuit through a second input on the integrated circuit,
routing the control signal to the delay circuit, where the control signal selectively engages and disengages the delay circuit based on tester settings,
where the delay circuit produces the delayed clock signal as a delay circuit output when the delay circuit is engaged and the delay circuit produces a low signal as the delay circuit output when the delay circuit is disengaged,
routing the delay circuit output to a second input on the XOR gate, thereby producing a test signal with the high frequency at an output of the XOR gate when the delay circuit is engaged and producing the test signal with the tester frequency when the delay circuit is disengaged, and
selectively routing the test signal to the high speed circuit.

10. The method of claim 9, wherein the method is implemented as part of a built in self test procedure for a high speed memory that operates at the high frequency, where the high frequency is greater than the test frequency that the tester can produce.

11. The method of claim 9, wherein the tester frequency is about two hundred megahertz and the high frequency is about four hundred megahertz.

12. The method of claim 9, wherein the high frequency is about twice the tester frequency.
